(19) United States
(12) Patent Application Publication
(10) Pub. No.: US 2010/0294327 A1
(43) Pub. Date: Nov. 25, 2010

(54) THERMOELECTRIC DEVICE USING RADIANT HEAT AS HEAT SOURCE AND METHOD OF FABRICATING THE SAME

(75) Inventors: Young Sam PARK, Daejeon (KR); Jung Wook Lim, Daejeon (KR); Moon Gyu Jang, Daejeon (KR)

Correspondence Address: AMPACC Law Group, 3500 188th Street S.W., Suite 103, Lynnwood, WA, 98037, US

(73) Assignee: Electronics and Telecommunications Research Institute, Daejeon (KR)

(21) Appl. No.: 12/773,226

(22) Filed: May 4, 2010

(30) Foreign Application Priority Data
May 21, 2009 (KR) 10-2009-0044632
Feb. 25, 2010 (KR) 10-2010-0016905

(51) Int. Cl. H01L 35/20; H01L 35/00; H01L 21/30; H01L 35/34

(52) U.S. Cl. 136/239; 136/200; 438/54; 136/201; 257/E21.211

(57) ABSTRACT

Provided are a thermoelectric device using radiant heat as a heat source and a method of fabricating the same. In the thermoelectric device, an anti-reflection layer formed on a heat absorption layer causes as much radiant light as possible to be absorbed by the heat absorption layer without being reflected to the outside so that the radiant heat absorption efficiency can be improved. Also, in the thermoelectric device, an insulating layer formed on a heat dissipation layer and a first reflection layer formed on the insulating layer can prevent external radiant heat from being absorbed by the heat dissipation layer, and as much radiant heat transferred to the heat dissipation layer as possible can be dissipated away from the heat dissipation layer by a second reflection layer thermally connected with the heat dissipation layer so that the radiant heat emission efficiency can be improved.

### CROSS-REFERENCE TO RELATED APPLICATION

This application claims priority to and the benefit of Korean Patent Application Nos. 10-2009-0044632, filed May 21, 2009 and 10-2010-0016905, filed Feb. 25, 2010, the disclosure of which is incorporated herein by reference in its entirety.

### BACKGROUND

1. Field of the Invention

The present invention relates to a thermoelectric device using radiant heat as a heat source and a method of fabricating the same, and more particularly to a thermoelectric device that uses radiant heat as a heat source and can maximize the heat absorption efficiency of a heat absorption layer and the heat dissipation efficiency of a heat dissipation layer and a method of fabricating the same.

2. Discussion of Related Art

Due to increases in population and industrial development, the human race has been confronted with problems of energy shortage and environmental pollution.

To solve these problems, many scientists are conducting research on finding new energy sources to replace existing fossil fuels.

As a result of such research, a thermoelectric device that can convert radiant heat, such as solar heat, subterranean heat, body heat, waste heat, etc., into electrical energy has been developed.

FIG. 1 is a block diagram of a conventional thermoelectric device.

Referring to FIG. 1, a thermoelectric device 100 includes a heat absorption layer 130, a leg 140, and a heat dissipation layer 150, and the leg 140 consists of a p-type leg 140p and an n-type leg 140n.

The heat absorption layer 130 absorbs external heat, the leg 140 transfers the heat absorbed by the heat absorption layer 130 to the heat dissipation layer 150, and the heat dissipation layer 150 dissipates the heat transferred from the leg 140 away from the heat dissipation layer 150.

Due to temperature difference between the heat absorption layer 130 and the heat dissipation layer 150, holes move from the heat absorption layer 130 toward the heat dissipation layer 150 in the p-type leg 140p, and electrons move from the heat absorption layer 130 toward to heat dissipation layer 150 in the n-type leg 140n. According to the movement of the holes and electrons, current flows counterclockwise.

To increase the thermoelectric efficiency of the thermoelectric device 100, the heat absorption layer 130 must absorb as much external heat as possible and transfer all the absorbed heat to the leg 140, and the leg 140 must transfer the heat transferred from the heat absorption layer 130 to the heat dissipation layer 150 as slowly as possible. And, the heat dissipation layer 150 must not absorb external heat at all but must dissipate the heat transferred from the leg 140 as much as possible.

In other words, the temperature difference between the heat absorption layer 130 and the heat dissipation layer 150 must be large for a high thermoelectric efficiency to be obtained.

As an indicator of a figure of merit, that is, thermoelectric efficiency of a thermoelectric device, a ZT value is used. The ZT value is proportional to the square of a Seebeck coefficient and electric conductivity, and is inversely proportional to thermal conductivity.

However, a thermoelectric device formed of metal has a very low Seebeck coefficient of several μV/K, and cannot have a high ZT value because electric conductivity is proportional to thermal conductivity according to the Wiedemann-Franz law.

To solve these problems, a thermoelectric device formed of a semiconductor is being developed. A typical thermoelectric device material may be Bi₂Te₃, which has a minimum ZT value of 0.7 at room temperature and a maximum ZT value of 0.9 at 120° C., and SiGe, which has a minimum ZT value of 0.1 at room temperature and a maximum ZT value of 0.9 at 900° C.

However, according to the late tendency of development and mass production of products employing thermoelectric devices, supplies of Bi₂Te₃ are predicted to become exhausted soon. For this reason, research on a material that can replace Bi₂Te₃, that is, a material having a minimum ZT value of 0.7 at room temperature is ongoing.

In this aspect, silicon has a very high thermal conductivity of about 150 W/mK and a ZT value of about 0.01, and thus has been considered difficult to use in thermoelectric devices. However, it has been lately reported that silicon nanowires grown by chemical vapor deposition (CVD) can reduce the thermal conductivity by 0.01 times or less and have a ZT value of almost 1. Thus, silicon nanowires are expected to be used in thermoelectric devices.

However, difficulty and complexity in fabricating silicon nanowires hinder mass production in an actual production step.

Meanwhile, solar heat is the most ideal heat source, since supply thereof is constant as long as the sun exists, and it causes no environmental pollution. Thus, if a high-efficiency thermoelectric device using radiant heat such as solar heat as a heat source is developed, it is expected to cause explosive demand due to marketability and applicability. However, research into a thermoelectric device using radiant heat such as solar heat as a heat source is still in its initial stages.

### SUMMARY OF THE INVENTION

The present invention is directed to implementing a high-efficiency thermoelectric device that uses radiant heat as a heat source, and can maximize the heat absorption efficiency of a heat absorption layer and the heat dissipation efficiency of a heat dissipation layer.

One aspect of the present invention provides a thermoelectric device using radiant heat as a heat source including: a substrate; a heat absorption layer formed on the substrate and absorbing radiant heat; a leg for transferring the heat absorbed by the heat absorption layer to a heat dissipation layer; the heat dissipation layer for dissipating the heat transferred from the leg away from the heat dissipation layer; an anti-reflection layer formed on the heat absorption layer and having a lower refractive index than the heat absorption layer; an insulating layer formed on the leg and the heat dissipation layer and having a lower refractive index than a first reflection layer; and the first reflection layer formed on the insulating layer and totally reflecting the radiant light. Here, the radiant light is not reflected to the outside due to the anti-reflection layer but is absorbed by the heat absorption layer, and the radiant light is not absorbed by the heat dissipation layer but is totally reflected by the insulating layer and the first reflection layer.

Another aspect of the present invention provides a method of fabricating a thermoelectric device using radiant heat as a heat source, the method including: forming, on a substrate, a heat absorption layer absorbing radiant heat, a leg transferring the heat absorbed by the heat absorption layer to a heat dissipation layer, and the heat dissipation layer dissipating the heat transferred from the leg away from the heat dissipation layer; forming an anti-reflection layer having a lower refractive index than the heat absorption layer on the heat absorption layer, and an insulating layer having a lower refractive index than a first reflection layer to be formed later on the heat dissipation layer; and forming the first reflection layer totally reflecting radiant light on the insulating layer.

### BRIEF DESCRIPTION OF THE DRAWINGS

The above and other objects, features and advantages of the present invention will become more apparent to those of ordinary skill in the art by describing in detail exemplary embodiments thereof with reference to the attached drawings, in which:

FIG. 1 is a block diagram of a conventional thermoelectric device;

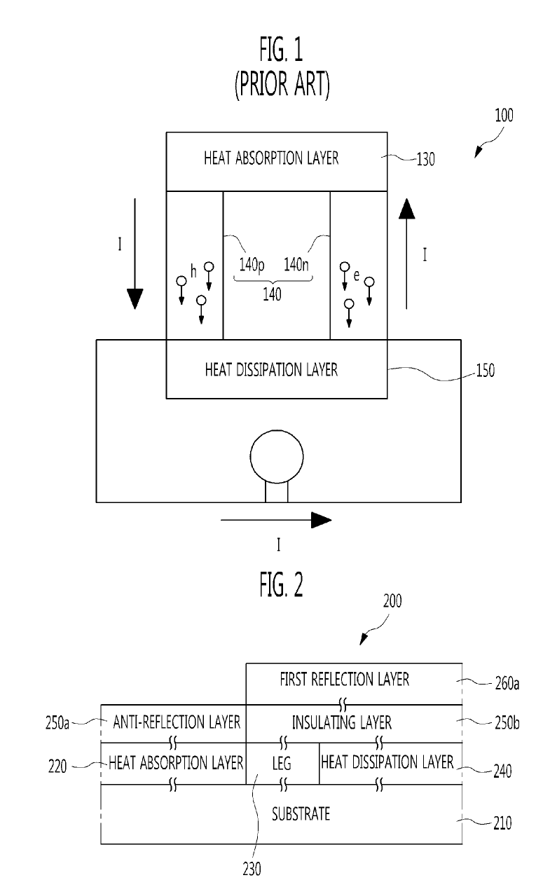

FIG. 2 is a cross-sectional block diagram of a thermoelectric device according to a first exemplary embodiment of the present invention;

FIG. 3 is a cross-sectional block diagram of a thermoelectric device according to a second exemplary embodiment of the present invention;

FIG. 4 is a cross-sectional block diagram of a thermoelectric device according to a third exemplary embodiment of the present invention; and

FIGS. 5A to 5E are cross-sectional block diagrams illustrating a method of fabricating a thermoelectric device according to an exemplary embodiment of the present invention.

### DETAILED DESCRIPTION OF EXEMPLARY EMBODIMENTS

Hereinafter, exemplary embodiments of the present invention will be described in detail. However, the present invention is not limited to the embodiments disclosed below but can be implemented in various forms. The following embodiments are described in order to enable those of ordinary skill in the art to embody and practice the present invention. Throughout this specification, when an element is referred to as “comprises,” “includes,” or “has” a component, it does not preclude another component but may further include the other component unless the context clearly indicates otherwise. In the drawings, the thickness of layers and regions may be exaggerated for clarity. When a layer is referred to as being “on” another layer or a substrate, it can be directly formed on the other layer or the substrate or an intervening layer may be present.

### First Exemplary Embodiment

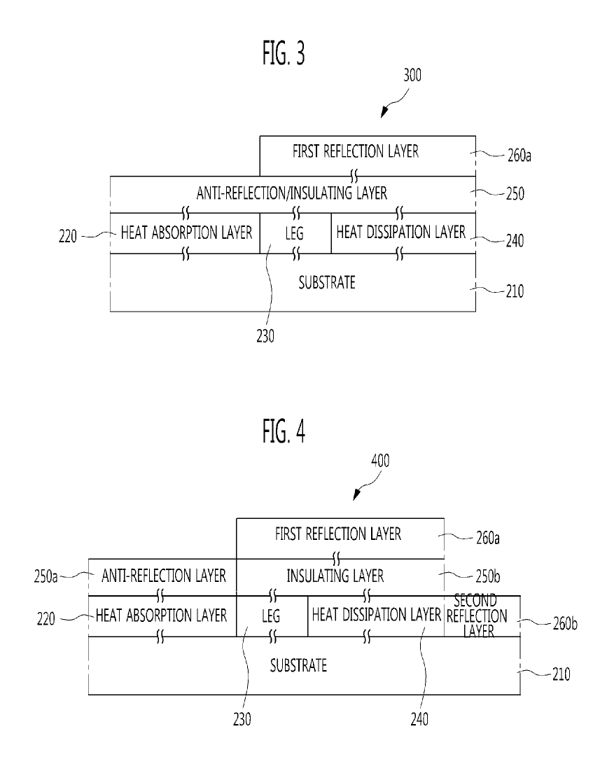

FIG. 2 is a cross-sectional block diagram of a thermoelectric device according to a first exemplary embodiment of the present invention.

Referring to FIG. 2, a thermoelectric device 200 according to the first exemplary embodiment of the present invention includes a heat absorption layer 220, a leg 230, and a heat dissipation layer 240 formed on a substrate 210, an anti-reflection layer 250a formed on the heat absorption layer 220, an insulating layer 250b formed on the leg 230 and the heat dissipation layer 240, and a first reflection layer 260a formed on the insulating layer 250b.

As the substrate 210, one of a silicon substrate, a glass substrate, a plastic substrate, a metal substrate, a silicon on insulator (SOI) substrate, and a multi-layer substrate in which these substrates are combined may be used.

The heat absorption layer 220 absorbs radiant heat such as solar heat, the leg 230 transfers the heat absorbed by the heat absorption layer 220 to the heat dissipation layer 240, and the heat dissipation layer 240 dissipates the heat transferred from the leg 230 away from the heat dissipation layer 240.

Here, the heat absorption layer 220 and the heat dissipation layer 240 may include at least one of group IV elements of the periodic table, Si, Ge, C, Sn and Pb, at least one of group V elements of the periodic table, Sb, As, Bi, P and N, or at least one of group VI elements of the periodic table, Te, Se, Po, S and O, and have a thickness of 10 nm to 1 cm.

The anti-reflection layer 250a causes external radiant light not to be reflected but to be absorbed by the heat absorption layer 220, which will be described in detail below.

The anti-reflection layer 250a is formed of a single dielectric layer or multiple dielectric layers having a lower refractive index than the heat absorption layer 220.

When external radiant light is incident on the anti-reflection layer 250a, it is not reflected at the interface between the anti-reflection layer 250a and the heat absorption layer 220 but is mostly transferred to the heat absorption layer 220 because the heat absorption layer 220 has a higher refractive index than the anti-reflection layer 250a. Thus, it is possible to increase the radiant heat absorption efficiency of the heat absorption layer 220.

In particular, when the refractive index of the anti-reflection layer 250a is adjusted to have a reflectance of 0 to 0.5 at a wavelength of radiant light to be absorbed, reflection of the radiant light is minimized so that the radiant heat absorption efficiency of the heat absorption layer 220 can be maximized.

When the anti-reflection layer 250a is formed of multiple dielectric layers, a dielectric layer having the lowest refractive index among the multiple dielectric layers may be formed in the uppermost layer, and dielectric layers may be formed in lower layers in order of increasing refractive indices. Then, it is possible to further increase the radiant heat absorption efficiency. Here, the refractive indices of all the dielectric layers must be lower than the refractive index of the heat absorption layer 220.

Meanwhile, the insulating layer 250b causes total reflection of the first reflection layer 260a while electrically and thermally insulating the heat dissipation layer 240 from external radiant heat, which will be described in detail below.

The insulating layer 250b is formed of a single dielectric layer or multiple dielectric layers having a lower refractive index than the first reflection layer 260a.

When external radiant light is incident on the first reflection layer 260a, it is totally reflected at the interface between the first reflection layer 260a and the insulating layer 250b because the first reflection layer 260a has a higher refractive index than the insulating layer 250b. Thus, it is possible to prevent the radiant heat from being absorbed by the heat dissipation layer 240.

Also, when the insulating layer 250b is formed of multiple dielectric layers, a dielectric layer having the lowest refractive index among the multiple dielectric layers may be formed in the uppermost layer, which is in contact with the first reflection layer 260a, and dielectric layers may be formed in lower layers in order of increasing refractive indices. Then, it is possible to further increase the radiant light reflection efficiency. Here, the refractive indices of all the dielectric layers must be lower than the refractive index of the first reflection layer 260a.

The first reflection layer 260a is formed of at least one of Al, Cu, Ti, Ag, Au, W, Si, Pt, Ni, Mo, Ta, Ir, Ru, Zn, Sn and In, and totally reflects external radiant light.

Thus, the thermoelectric device 200 according to the first exemplary embodiment of the present invention can maximize the heat absorption efficiency of the heat absorption layer 220 due to the anti-reflection layer 250a, and has excellent thermoelectric efficiency because the first reflection layer 260a and the insulating layer 250b can prevent external radiant heat from being absorbed by the heat dissipation layer 240.

### Second Exemplary Embodiment

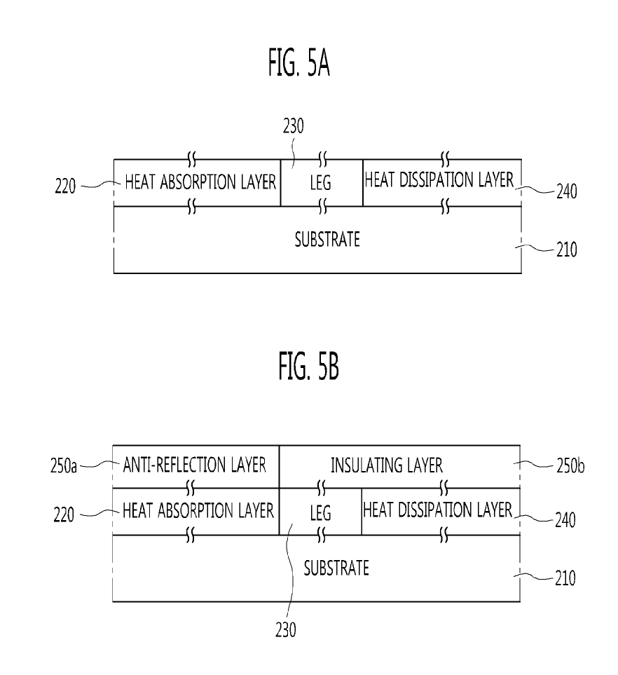

FIG. 3 is a cross-sectional block diagram of a thermoelectric device according to a second exemplary embodiment of the present invention.

Referring to FIG. 3, a thermoelectric device 300 according to the second exemplary embodiment of the present invention includes the same components as the thermoelectric device 200 shown in FIG. 2 except that the anti-reflection layer 250a and the insulating layer 250b are replaced by one anti-reflection/insulating layer 250 to simplify its fabrication process.

Here, the anti-reflection/insulating layer 250 must have a refractive index that is lower than those of the heat absorption layer 220 and the first reflection layer 260a.

### Third Exemplary Embodiment

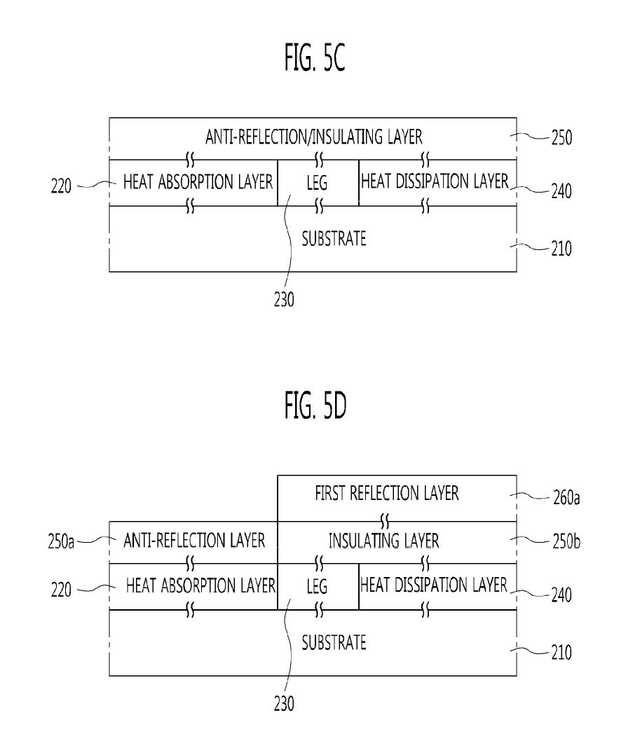

FIG. 4 is a cross-sectional block diagram of a thermoelectric device according to a third exemplary embodiment of the present invention.

Referring to FIG. 4, a thermoelectric device 400 according to the third exemplary embodiment of the present invention includes the same components as the thermoelectric device 200 shown in FIG. 2 except that a second reflection layer 260b is formed to be thermally connected with the heat dissipation layer 240.

Here, the second reflection layer 260b is formed to have a higher thermal conductivity (e.g., 10 W/mK or more) than the heat dissipation layer 240, and dissipates as much heat transferred to the heat dissipation layer 240 as possible away from the heat dissipation layer 240. Also, the second reflection layer 260b functions as a metal interconnection.

Here, the second reflection layer 260b is formed of at least one of Al, Cu, Ti, Ag, Au, W, Si, Pt, Ni, Mo, Ta, Ir, Ru, Zn, Sn and In.

Since the thermoelectric device 400 according to the third exemplary embodiment of the present invention can dissipate as much heat transferred to the heat dissipation layer 240 as possible away from the heat dissipation layer due to the second reflection layer 260b, it can maximize the heat dissipation efficiency of the heat dissipation layer 240 and does not require an additional metal interconnection for connection with an external circuit.

A method of fabricating a thermoelectric device according to an exemplary embodiment of the present invention will be described below.

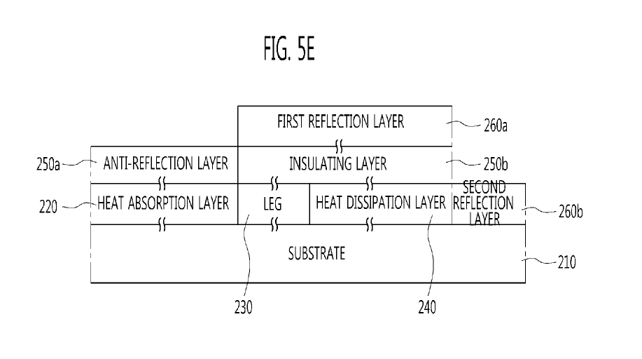

FIGS. 5A to 5E are cross-sectional block diagrams illustrating a method of fabricating a thermoelectric device according to an exemplary embodiment of the present invention.

In the first step, as illustrated in FIG. 5A, a heat absorption layer 220, a leg 230, and a heat dissipation layer 240 are formed on a substrate 210.

In the second step, as illustrated in FIG. 5B, an anti-reflection layer 250a is formed on the heat absorption layer 220, and an insulating layer 250b is formed on the leg 230 and the heat dissipation layer 240.

Here, each of the anti-reflection layer 250a and the insulating layer 250b is formed of single dielectric layers formed by depositing one of a low dielectric material (e.g., an oxide or nitride such as Al₂O₃, SiO₂ or SiN) having a low dielectric constant of less than 10, a high dielectric material (e.g., an oxide such as TiO₂, ZrO₂, HfO₂, Ta₂O₅ or ZnO) having a high dielectric constant of 10 or more, and a compound of the low dielectric material and the high dielectric material, or multiple dielectric layers formed by successively depositing the low dielectric material and the high dielectric material. And, the anti-reflection layer 250a and the insulating layer 250b may be formed by atomic layer deposition, plasma atomic layer deposition, sputtering, chemical vapor deposition (CVD), thermal oxidation, etc., or formed by the sol-gel method, spin coating, etc., for mass production.

When the anti-reflection layer 250a is formed by atomic layer deposition, the refractive index of the anti-reflection layer 250a may be adjusted to change reflectance during the deposition process, which will be described in detail below.

For example, when the anti-reflection layer 250a of AlTiO (ATO) is formed by atomic layer deposition using Al₂O₃ having a relatively low refractive index of 1.6 to 1.7 and TiO₂ having a relatively high refractive index of 2.4 to 2.5, the composition of Ti in the anti-reflection layer 250a of ATO is changed by adjusting a cycle ratio of atomic layer deposition. The change in composition leads to a change in the refractive index of the anti-reflection layer 250a of ATO, resulting in a change in reflectance.

Thus, when the refractive index of the anti-reflection layer 250a is adjusted to be lower than that of the heat absorption layer 220 while the anti-reflection layer 250a is formed by atomic layer deposition, radiant light is not reflected by the anti-reflection layer 250a but is absorbed by the heat absorption layer 220 so that radiant heat absorption efficiency can be improved.

In particular, when the refractive index of the anti-reflection layer 250a is adjusted to have a reflectance of 0 to 0.5 at a wavelength of radiant light to be absorbed, the radiant heat absorption efficiency of the heat absorption layer 220 can be maximized.

When the anti-reflection layer 250a is formed of multiple dielectric layers, a dielectric layer having the lowest refractive index among the multiple dielectric layers may be formed in the uppermost layer, and dielectric layers may be formed in lower layers in order of increasing refractive indices. Then, it is possible to further increase the radiant heat absorption efficiency. Here, the refractive indices of all the dielectric layers must be lower than the refractive index of the heat absorption layer 220.

Likewise, when the insulating layer 250b is formed by atomic layer deposition, the refractive index of the insulating layer 250b may be adjusted to be lower than that of the first reflection layer 260a to be formed on the insulating layer 250b during the deposition process. Then, the insulating layer 250b that has a lower refractive index than the first reflection layer 260a can prevent external radiant heat from being absorbed by the heat dissipation layer 240.

When the insulating layer 250b is formed of multiple dielectric layers, a dielectric layer having the lowest refractive index among the multiple dielectric layers may be formed in the uppermost layer, which is in contact with the first reflection layer 260a, and dielectric layers may be formed in lower layers in order of increasing refractive indices. Then, it is possible to further increase the radiant light reflection efficiency. Here, the refractive indices of all the dielectric layers must be lower than the refractive index of the first reflection layer 260a.

Since a dielectric layer can be formed at a relatively low temperature of about 100 to 300° C. by the atomic layer deposition technique used in this exemplary embodiment, the anti-reflection layer 250a and the insulating layer 250b may be formed on a silicon substrate, a glass substrate, a metal substrate, a SOI substrate, or a multi-layer substrate in which these substrates are combined. Also, the anti-reflection layer 250a and the insulating layer 250b may be formed on a plastic substrate requiring a process temperature of 150° C. or less. Furthermore, using the atomic layer deposition technique, several dielectric materials can be successively deposited in a vacuum according to a previously-programmed process without stopping the process, similarly to when one material is deposited.

Meanwhile, in the second step, as illustrated in FIG. 5C, the anti-reflection layer 250a and the insulating layer 250b may be simultaneously formed to simplify the fabrication process. In this case, one anti-reflection/insulating layer 250 is formed on the heat absorption layer 220, the leg 230, and the heat dissipation layer 240.

Subsequently, in the third step, as illustrated in FIG. 5D, a first reflection layer 260a that totally reflects external radiant light is formed on the insulating layer 250b. At this time, the first reflection layer 260a is formed of at least one of Al, Cu, Ti, Ag, Au, W, Si, Pt, Ni, Mo, Ta, Ir, Ru, Zn, Sn and In.

Here, as illustrated in FIG. 5E, a second reflection layer 260b that is thermally connected with the heat dissipation layer 240 and has a higher thermal conductivity (e.g., 10 W/mK or more) than the heat dissipation layer 240 may be formed to improve the heat dissipation efficiency of the heat dissipation layer 240.

The second reflection layer 260b is formed of at least one of Al, Cu, Ti, Ag, Au, W, Si, Pt, Ni, Mo, Ta, Ir, Ru, Zn, Sn and In.

In this case, the second reflection layer 260b dissipates as much heat transferred to the heat dissipation layer 240 as possible away from the heat dissipation layer 240, and also functions as a metal interconnection.

According to an exemplary embodiment of the present invention, it is possible to implement a high-efficiency thermoelectric device that uses radiant heat as a heat source and can maximize the heat absorption efficiency of a heat absorption layer and the heat dissipation efficiency of a heat dissipation layer.

While the invention has been shown and described with reference to certain exemplary embodiments thereof, it will be understood by those skilled in the art that various changes in form and details may be made therein without departing from the spirit and scope of the invention as defined by the appended claims.

What is claimed is:

1. A thermoelectric device using radiant heat as a heat source, comprising:
a substrate;
a heat absorption layer formed on the substrate and absorbing radiant heat;
a leg for transferring the heat absorbed by the heat absorption layer to a heat dissipation layer;
the heat dissipation layer for dissipating the heat transferred from the leg away from the heat dissipation layer;
an anti-reflection layer formed on the heat absorption layer and having a lower refractive index than the heat absorption layer;
an insulating layer formed on the leg and the heat dissipation layer and having a lower refractive index than a first reflection layer; and
the first reflection layer formed on the insulating layer and totally reflecting the radiant light,
wherein the radiant light is not reflected to the outside due to the anti-reflection layer but is absorbed by the heat absorption layer, and the radiant light is not absorbed by the heat dissipation layer but is totally reflected by the insulating layer and the first reflection layer.

2. The thermoelectric device of claim 1, wherein the substrate is one of a silicon substrate, a glass substrate, a plastic substrate, a metal substrate, a silicon on insulator (SOI) substrate, and a multi-layer substrate in which these substrates are combined.

3. The thermoelectric device of claim 1, wherein the heat absorption layer and the heat dissipation layer include at least one of group IV elements of the periodic table, Si, Ge, C, Sn and Pb, at least one of group V elements of the periodic table, Sb, As, Bi, P and N, or at least one of group VI elements of the periodic table, Te, Se, Po, S and O.

4. The thermoelectric device of claim 1, wherein the anti-reflection layer is formed of a single dielectric layer or multiple dielectric layers having a lower refractive index than the heat absorption layer.

5. The thermoelectric device of claim 4, wherein the anti-reflection layer has a reflectance of 0 to 0.5 at a wavelength of the radiant light to be absorbed.

6. The thermoelectric device of claim 4, wherein when the anti-reflection layer is formed of multiple dielectric layers, a dielectric layer having the lowest refractive index is formed in the uppermost layer, and dielectric layers are formed in lower layers in order of increasing refractive indices.

7. The thermoelectric device of claim 1, wherein the insulating layer is formed of a single dielectric layer or multiple dielectric layers having a lower refractive index than the first reflection layer.

8. The thermoelectric device of claim 7, wherein when the insulating layer is formed of multiple dielectric layers, a dielectric layer having the lowest refractive index is formed in the uppermost layer, and dielectric layers are formed in lower layers in order of increasing refractive indices.

9. The thermoelectric device of claim 1, further comprising a second reflection layer formed to be thermally connected with the heat dissipation layer and have a higher thermal conductivity than the heat dissipation layer, and dissipating the heat transferred to the heat dissipation layer away from the heat dissipation layer.

10. The thermoelectric device of claim 9, wherein the first and second reflection layers are formed of at least one of Al, Cu, Ti, Ag, Au, W, Si, Pt, Ni, Mo, Ta, Ir, Ru, Zn, Sn and In.

11. A method of fabricating a thermoelectric device using radiant heat as a heat source, the method comprising:
forming, on a substrate, a heat absorption layer absorbing radiant heat, a leg transferring the heat absorbed by the heat absorption layer to a heat dissipation layer, and the heat dissipation layer dissipating the heat transferred from the leg away from the heat dissipation layer;
forming an anti-reflection layer having a lower refractive index than the heat absorption layer on the heat absorption layer, and an insulating layer having a lower refractive index than a first reflection layer to be formed later on the heat dissipation layer; and
forming the first reflection layer totally reflecting radiant light on the insulating layer.

12. The method of claim 11, wherein forming the anti-reflection layer and the insulating layer includes forming each of the anti-reflection layer and the insulating layer to have a single dielectric layer or multiple dielectric layers by one of atomic layer deposition, chemical vapor deposition (CVD), and sputtering.

13. The method of claim 12, wherein forming the anti-reflection layer and the insulating layer further includes adjusting the refractive index of the anti-reflection layer to be lower than that of the heat absorption layer while the anti-reflection layer is formed.

14. The method of claim 13, wherein forming the anti-reflection layer and the insulating layer further includes adjusting the refractive index of the anti-reflection layer to have a reflectance of 0 to 0.5 at a wavelength of the radiant light to be absorbed.

15. The method of claim 13, wherein forming the anti-reflection layer and the insulating layer further includes, when the anti-reflection layer is formed of multiple dielectric layers, forming a dielectric layer having the lowest refractive index in the uppermost layer and dielectric layers in lower layers in order of increasing refractive indices.

16. The method of claim 12, wherein forming the anti-reflection layer and the insulating layer further includes adjusting the refractive index of the insulating layer to be lower than that of the first reflection layer while the insulating layer is formed.

17. The method of claim 16, wherein forming the anti-reflection layer and the insulating layer further includes, when the insulating layer is formed of multiple dielectric layers, forming a dielectric layer having the lowest refractive index in the uppermost layer and dielectric layers in lower layers in order of increasing refractive indices.

18. The method of claim 11, wherein forming the anti-reflection layer and the insulating layer includes simultaneously forming the anti-reflection layer and the insulating layer to have a single dielectric layer or multiple dielectric layers by one of atomic layer deposition, chemical vapor deposition (CVD), and sputtering.

19. The method of claim 11, wherein forming the first reflection layer includes forming a second reflection layer thermally connected with the heat dissipation layer and having a higher thermal conductivity than the heat dissipation layer.
